(19) United States
(12) Patent Application Publication
(10) Pub. No.: US 2025/0372429 A1
(43) Pub. Date: Dec. 4, 2025

(54) LIFTING MECHANISM, SUBSTRATE PROCESSING APPARATUS AND LIFTING METHOD

(71) Applicant: Tokyo Electron Limited, Tokyo (JP)

(72) Inventor: Manabu HONMA, Oshu City (JP)

(21) Appl. No.: 19/223,468

(22) Filed: May 30, 2025

(30) Foreign Application Priority Data
Jun. 3, 2024 (JP) 2024-089880

(51) Int. Cl. H01L 21/677; B66F 7/02

(52) U.S. Cl. CPC H01L 21/67757; B66F 7/025; H01L 21/67742

(57) ABSTRACT

A lifting mechanism for raising and lowering a substrate holder that holds a plurality of substrates in a shelf-like manner, includes: a support configured to support the substrate holder; a first lifter connected to the support and configured to raise and lower the support; and a second lifter provided in parallel with the first lifter and configured to raise and lower the first lifter.

### CROSS-REFERENCE TO RELATED APPLICATION

This application is based upon and claims the benefit of priority from Japanese Patent Application No. 2024-089880, filed on Jun. 3, 2024, the entire contents of which are incorporated herein by reference.

### TECHNICAL FIELD

The present disclosure relates to a lifting mechanism, a substrate processing apparatus, and a lifting method.

### BACKGROUND

A technique is known in which a boat supporting a plurality of substrates is raised and lowered by a boat elevator.

### PRIOR ART DOCUMENTS

### Patent Documents

Patent Document 1: Japanese Patent Laid-Open Publication No. 2002-359237

Patent Document 2: Japanese Patent Laid-Open Publication No. 2004-281881

### SUMMARY

According to one embodiment of the present disclosure, there is provided a lifting mechanism for raising and lowering a substrate holder that holds a plurality of substrates in a shelf-like manner, including: a support configured to support the substrate holder; a first lifter connected to the support and configured to raise and lower the support; and a second lifter provided in parallel with the first lifter and configured to raise and lower the first lifter.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is cross-sectional view (1) showing a substrate processing apparatus according to a first embodiment.

FIG. 2 is cross-sectional view (2) showing the substrate processing apparatus according to the first embodiment.

FIG. 3 is a cross-sectional view showing a lifting mechanism according to a first example.

FIG. 4 is cross-sectional view (1) showing an example of the operation of the lifting mechanism according to the first example.

FIG. 5 is cross-sectional view (2) showing an example of the operation of the lifting mechanism according to the first example.

FIG. 6 is cross-sectional view (3) showing an example of the operation of the lifting mechanism according to the first example.

FIG. 7 is cross-sectional view (4) showing an example of the operation of the lifting mechanism according to the first example.

FIG. 8 is cross-sectional view (5) showing an example of the operation of the lifting mechanism according to the first example.

FIG. 9 is cross-sectional view (1) showing another example of the operation of the lifting mechanism according to the first example.

FIG. 10 is cross-sectional view (2) showing another example of the operation of the lifting mechanism according to the first example.

FIG. 11 is cross-sectional view (3) showing another example of the operation of the lifting mechanism according to the first example.

FIG. 12 is cross-sectional view (4) showing another example of the operation of the lifting mechanism according to the first example.

FIG. 13 is cross-sectional view (5) showing another example of the operation of the lifting mechanism according to the first example.

FIG. 14 is a cross-sectional view showing a lifting mechanism according to a second example.

FIG. 15 is cross-sectional view (1) showing an example of the operation of the lifting mechanism according to the second example.

FIG. 16 is cross-sectional view (2) showing an example of the operation of the lifting mechanism according to the second example.

FIG. 17 is cross-sectional view (3) showing an example of the operation of the lifting mechanism according to the second example.

FIG. 18 is cross-sectional view (4) showing an example of the operation of the lifting mechanism according to the second example.

FIG. 19 is cross-sectional view (5) showing an example of the operation of the lifting mechanism according to the second example.

FIG. 20 is cross-sectional view (1) showing a substrate processing apparatus according to a second embodiment.

FIG. 21 is cross-sectional view (2) showing the substrate processing apparatus according to the second embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-limiting exemplary embodiments of the present disclosure will be described with reference to the accompanying drawings. Throughout the accompanying drawings, the same or corresponding members or parts are designated by the same or corresponding reference numerals, and the duplicated descriptions thereof will be omitted.

### First Embodiment

### Substrate Processing Apparatus

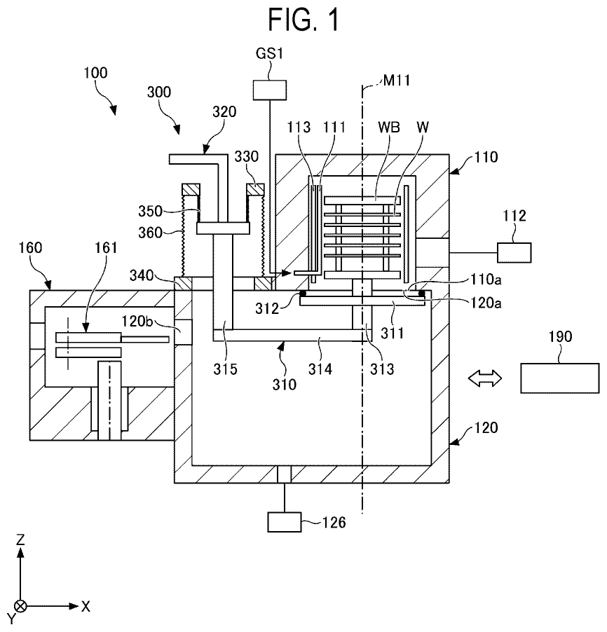

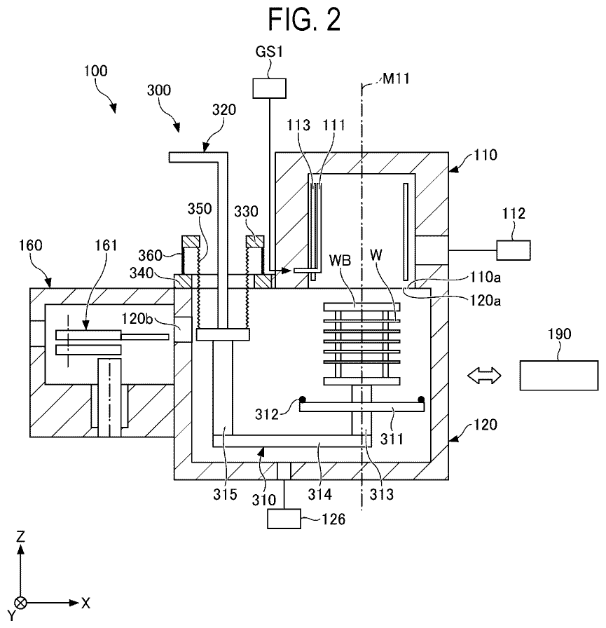

A substrate processing apparatus 100 according to a first embodiment will be described with reference to FIGS. 1 and 2. FIGS. 1 and 2 are cross-sectional views showing the substrate processing apparatus 100 according to the first embodiment. FIG. 1 shows a state in which a substrate holder WB is at a processing position. FIG. 2 shows a state in which the substrate holder WB is at a transfer position.

The substrate processing apparatus 100 includes a processing chamber 110, a load lock chamber 120, a substrate transfer chamber 160, and a controller 190.

The processing chamber 110 is capable of depressurizing an interior of the processing chamber 110. The processing chamber 110 accommodates a substrate holder WB in the interior of the processing chamber 110. The substrate holder WB holds a plurality of substrates W in a shelf-like manner. The substrate W is, for example, a semiconductor wafer. Although five substrates W are shown in FIG. 1 and FIG. 2, the number of substrates W is not limited. In the processing chamber 110, the substrates W held by the substrate holder WB are processed at the same time. A loading/unloading port 110a for loading and unloading the substrate holder WB is provided at the bottom of the processing chamber 110. The processing chamber 110 is provided with a gas nozzle 111, an exhaust device 112, and a heater 113.

The gas nozzle 111 is provided around the substrate holder WB located in the processing chamber 110. The gas nozzle 111 injects a processing gas supplied from a gas source GS1 from around the substrate holder WB located in the processing chamber 110 toward the substrate holder WB and the substrates W. The processing gas may be selected depending on the type of processing. The number of gas nozzles 111 may be one, or may be two or more.

The exhaust device 112 evacuates the interior of the processing chamber 110 to reduce the pressure inside the processing chamber 110. The exhaust device 112 includes, for example, a vacuum pump and a pressure control valve. The exhaust device 112 controls the pressure inside the processing chamber 110 to a predetermined pressure by adjusting the opening degree of the pressure control valve while evacuating the interior of the processing chamber 110 with the vacuum pump. The predetermined pressure may be set depending on the type of processing.

The heater 113 is provided in the processing chamber 110. The heater 113 may be provided around the substrate holder WB located in the processing chamber 110. The heater 113 heats the substrate holder WB and the substrates W to a predetermined temperature from around the substrate holder WB located in the processing chamber 110. The predetermined temperature may be set depending on the type of processing.

The load lock chamber 120 is located below the processing chamber 110. The load lock chamber 120 is capable of depressurizing an interior of the load lock chamber 120. The load lock chamber 120 accommodates the substrate holder WB in the interior of the load lock chamber 120. A loading/unloading port 120a for loading and unloading the substrate holder WB is provided at the top of the load lock chamber 120. The interior of the load lock chamber 120 communicates with the interior of the processing chamber 110 via the loading/unloading port 110a and the loading/unloading port 120a. The substrate holder WB is loaded from the interior of the load lock chamber 120 into the interior of the processing chamber 110 via the loading/unloading port 110a and the loading/unloading port 120a. The substrate holder WB is unloaded from the interior of the processing chamber 110 into the load lock chamber 120 via the loading/unloading port 110a and the loading/unloading port 120a. In the load lock chamber 120, the substrates W are loaded to the substrate holder WB and unloaded from the substrate holder WB. A loading/unloading port 120b for loading and unloading the substrates W is provided on a sidewall of the load lock chamber 120 on the negative side in the X-axis direction. The substrates W are loaded from the substrate transfer chamber 160 into the load lock chamber 120 via the loading/unloading port 120b. The substrates W are unloaded from the load lock chamber 120 into the substrate transfer chamber 160 via the loading/unloading port 120b. An exhaust device 126 and a lifting mechanism 300 are provided in the load lock chamber 120.

The exhaust device 126 evacuates the interior of the load lock chamber 120 to reduce the pressure inside the load lock chamber 120. The exhaust device 126 includes, for example, a vacuum pump and a pressure control valve. The exhaust device 126 adjusts the opening degree of the pressure control valve while evacuating the load lock chamber 120 with the vacuum pump, thereby controlling the pressure inside the load lock chamber 120 to a predetermined pressure. The predetermined pressure may be the same as the pressure inside the processing chamber 110.

The lifting mechanism 300 is configured to raise and lower the substrate holder WB between the processing position (see FIG. 1) and the transfer position (see FIG. 2). The processing position may be a position where the substrate holder WB is entirely accommodated in the processing chamber 110 and the loading/unloading port 110a and the loading/unloading port 120a are air-tightly closed by a lid 311. The transfer position may be a position directly below the processing position and may be a position where the substrate holder WB is entirely accommodated in the load lock chamber 120. The transfer position may be a position where a part of the substrate holder WB faces the loading/unloading port 120b.

The lifting mechanism 300 includes a support 310, a lifter 320, a first flange 330, a second flange 340, an inner bellows 350, and an outer bellows 360.

The support 310 supports the substrate holder WB and includes the lid 311, a seal member 312, a rotary shaft 313, a support arm 314, and a shaft 315.

When the substrate holder WB is positioned in the processing chamber 110, the lid 311 airtightly closes the loading/unloading port 110a and the loading/unloading port 120a using the seal member 312. This seals the processing chamber 110 airtight. The seal member 312 is, for example, an O-ring. A through-hole that penetrates the lid 311 in the vertical direction is provided at the center of the lid 311. The rotary shaft 313 is inserted into the through-hole. A gap between the lid 311 and the rotary shaft 313 is sealed by a magnetic fluid seal. The rotary shaft 313 supports the substrate holder WB so that it can rotate the substrate holder WB around a vertical axis M11. One end of the support arm 314 is fixed to a lower portion of the rotary shaft 313. The support arm 314 supports the rotary shaft 313. The shaft 315 is fixed to the other end of the support arm 314. The shaft 315 penetrates through a ceiling of the load lock chamber 120 and extends to above the load lock chamber 120.

The lifter 320 is connected to the support 310. The lifter 320 raises and lowers the support 310 between an upper end position and a lower end position, thereby vertically moving the substrate holder WB between the processing position and the transfer position. For example, the lifter 320 raises the support 310 from the lower end position to the upper end position, thereby loading the substrate holder WB from the transfer position to the processing position. For example, the lifter 320 lowers the support 310 from the upper end position to the lower end position, thereby unloading the substrate holder WB from the processing position to the transfer position.

As shown in FIG. 1, the upper end position is a position where a length of the inner bellows 350 is shorter than a length of the outer bellows 360. The upper end position may be a position where the length of the inner bellows 350 is at its minimum and the length of the outer bellows 360 is at its maximum. The upper end position may be a position where an upper surface of the shaft 315 is at a height between the first flange 330 and the second flange 340. The upper end position may be a position where the upper surface of the shaft 315 is above the ceiling of the load lock chamber 120.

As shown in FIG. 2, the lower end position is a position where the length of the inner bellows 350 is longer than the length of the outer bellows 360. The lower end position may be a position where the length of the inner bellows 350 is at its maximum and the length of the outer bellows 360 is at its minimum. The lower end position may be a position where the upper surface of the shaft 315 is below the second flange 340. The lower end position may be a position where the upper surface of the shaft 315 is below the ceiling of the load lock chamber 120.

The lifter 320 may be expandable. In this case, it is possible to prevent the lifter 320 from jumping out above the ceiling of the processing chamber 110. The lifter 320 raises the support 310 by being retracted. The lifter 320 lowers the support 310 by being expanded.

The first flange 330 is provided above the shaft 315. The first flange 330 has a circular ring plate shape. The height position of the first flange 330 is changeable.

The second flange 340 is provided below the first flange 330. The second flange 340 has a circular ring plate shape. The height position of the second flange 340 is fixed. The second flange 340 may be fixed to the ceiling of the load lock chamber 120.

The inner bellows 350 has an expandable retractable bellows tube shape. The inner bellows 350 connects the shaft 315 and the first flange 330 in an expandable retractable manner. The inner bellows 350 is expanded and retracted as the support 310 is raised and lowered. The inner bellows 350 is retracted when raising the support 310, and is expanded when lowering the support 310. The inner bellows 350 is an example of a first expandable portion.

The outer bellows 360 has an expandable retractable bellows tube shape. The outer bellows 360 is provided around the inner bellows 350. The outer bellows 360 connects the first flange 330 and the second flange 340 in an expandable retractable manner. The outer bellows 360 is expanded and retracted as the support 310 is raised and lowered. The outer bellows 360 is expanded when raising the support 310, and is retracted when lowering the support 310. In other words, the outer bellows 360 is expanded and retracted in a direction opposite to the expanding and retracting direction of the inner bellows 350 when raising and lowering the support 310. In this case, this may result in saving space. The central axis of the outer bellows 360 may coincide with the central axis of the inner bellows 350. The inner diameter of the outer bellows 360 may be larger than the outer diameter of the inner bellows 350. The inner bellows 350 and the outer bellows 360 airtightly separate the internal space and the external space of the load lock chamber 120. By providing the inner bellows 350 and the outer bellows 360, it is possible to raise and lower the support 310 while maintaining the airtightness inside the load lock chamber 120. The outer bellows 360 is an example of a second expandable portion.

The substrate transfer chamber 160 is connected to the X-axis negative side of the load lock chamber 120. The substrate transfer chamber 160 is capable of depressurizing an interior of the substrate transfer chamber 160. A substrate transfer robot 161 is provided in the substrate transfer chamber 160. An exhaust device may be provided in the substrate transfer chamber 160.

The substrate transfer robot 161 is provided in the substrate transfer chamber 160. The substrate transfer robot 161 loads the substrates W to the substrate holder WB at the transfer position via the loading/unloading port 120b. The substrate transfer robot 161 unloads the substrates W held by the substrate holder WB at the transfer position via the loading/unloading port 120b. The substrate transfer robot 161 may include a horizontal articulated arm.

The controller 190 is an electronic circuit such as a central processing unit (CPU), a field programmable gate array (FPGA), an application specific integrated circuit (ASIC), or the like. The controller 190 executes various control operations described in this specification by executing instruction codes stored in a computer readable memory or by being circuit-designed for a specific purpose.

As described above, according to the first embodiment, the lifting mechanism 300 includes the support 310, the lifter 320, the inner bellows 350, and the outer bellows 360. The support 310 supports the substrate holder WB. The lifter 320 is connected to the support 310 to raise and lower the support 310. The inner bellows 350 is expanded and retracted as the support 310 is raised and lowered. The outer bellows 360 is expanded and retracted as the support 310 is raised and lowered. The direction of expansion and retraction of the outer bellows 360 when raising and lowering the support 310 is opposite to that of the inner bellows 350. In this case, when the support 310 is at the lower end position, an upper surface of the support 310 is located below the ceiling of the load lock chamber 120. Therefore, the height by which the upper surface of the support 310 protrudes above the ceiling of the load lock chamber 120 when raising the support 310 to the upper end position is reduced. This allows the upper surface of the support 310 to be located below the ceiling of the processing chamber 110. As a result, it is possible to reduce the height of the substrate processing apparatus 100.

### Lifting Mechanism

### First Example

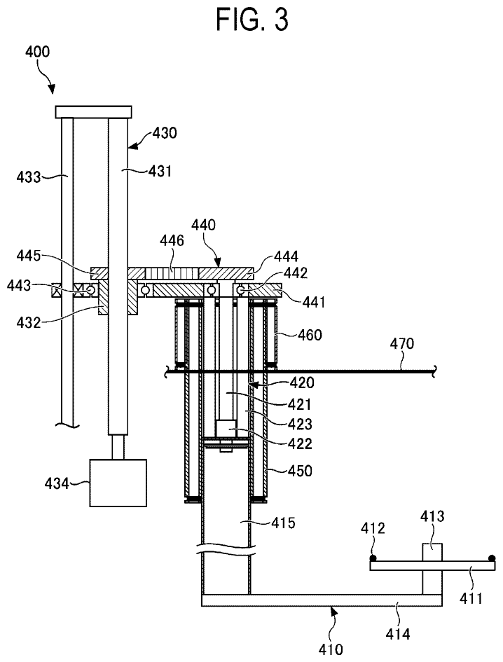

A lifting mechanism 400 according to a first example will be described with reference to FIG. 3. FIG. 3 is a cross-sectional view showing the lifting mechanism 400 according to the first example. The lifting mechanism 400 is applicable as the lifting mechanism 300 provided in the substrate processing apparatus 100.

The lifting mechanism 400 includes a support 410, a first lifter 420, a second lifter 430, a transmission 440, an inner bellows 450, and an outer bellows 460.

The support 410 supports the substrate holder WB. The support 410 includes a lid 411, a seal member 412, a rotary shaft 413, a support arm 414, and a shaft 415. The lid 411, the seal member 412, the rotary shaft 413, the support arm 414, and the shaft 415 may have the same configurations as the lid 311, the seal member 312, the rotary shaft 313, the support arm 314, and the shaft 315, respectively.

The first lifter 420 raises and lowers the support 410. The first lifter 420 includes a first screw shaft 421, a first nut 422, and a first guide rail 423.

The first screw shaft 421 extends vertically. The first screw shaft 421 is rotatably supported by a first bearing 442.

The first nut 422 is threadedly coupled to the first screw shaft 421 so as to be raised and lowered. The first nut 422 is raised and lowered along the first screw shaft 421 as the first screw shaft 421 rotates. The first nut 422 converts the rotational motion of the first screw shaft 421 into linear motion thereof. The shaft 415 is fixed to the first nut 422. The part where the first screw shaft 421 and the first nut 422 are threadedly coupled may include a ball screw mechanism.

The first guide rail 423 is provided in parallel with the first screw shaft 421. The first guide rail 423 guides the raising and lowering of the shaft 415. The number of first guide rails 423 is not limited, and may be, for example, two.

The second lifter 430 raises and lowers the first lifter 420. The second lifter 430 includes a second screw shaft 431, a second nut 432, a second guide rail 433, and a second motor 434.

The second screw shaft 431 is provided in parallel to the first screw shaft 421. The second screw shaft 431 is rotatably supported by a second bearing 443.

The second nut 432 is threadedly coupled to the second screw shaft 431 so as to be raised and lowered. The second nut 432 is raised and lowered along the second screw shaft 431 as the second screw shaft 431 rotates. The second nut 432 converts the rotational motion of the second screw shaft 431 into linear motion thereof. The part where the second screw shaft 431 and the second nut 432 are threadedly coupled may include a ball screw mechanism.

The second guide rail 433 is provided in parallel with the second screw shaft 431. The second guide rail 433 guides the raising and lowering of a bracket 441. The number of second guide rails 433 is not limited, and may be, for example, one.

The second motor 434 applies a driving force to the second screw shaft 431 to rotate the second screw shaft 431. The second motor 434 may be connected to a lower end of the second screw shaft 431.

The transmission 440 transmits the driving force of the second lifter 430 to the first lifter 420. The transmission 440 includes the bracket 441, a first bearing 442, a second bearing 443, a first timing pulley 444, a second timing pulley 445, and a timing belt 446.

The bracket 441 supports the upper end of the first guide rail 423. The first bearing 442 and the second bearing 443 are fixed to the bracket 441. The first bearing 442 rotatably supports the first screw shaft 421. The second bearing 443 rotatably supports the second nut 432. The first timing pulley 444 is fixed to the upper end of the first screw shaft 421 and is rotated together with the first screw shaft 421. The second timing pulley 445 is fixed to the second nut 432 and is rotated together with the second nut 432. The timing belt 446 meshes with the first timing pulley 444 and the second timing pulley 445 and transmits a rotational force between the first timing pulley 444 and the second timing pulley 445.

The inner bellows 450 has an expandable retractable bellows tube shape. The inner bellows 450 connects the shaft 415 and the outer bellows 460 in an expandable retractable manner. An upper portion of the inner bellows 450 and an upper portion of the outer bellows 460 are connected. A portion where the inner bellows 450 and the outer bellows 460 are connected functions as a first flange. The inner bellows 450 is expanded and retracted as the support 410 is raised and lowered. The inner bellows 450 is retracted when raising the support 410, and is expanded when lowering the support 410. The inner bellows 450 is an example of a first expandable portion.

The outer bellows 460 has an expandable retractable bellows tube shape. The outer bellows 460 is provided around the inner bellows 450. The outer bellows 460 connects the inner bellows 450 and a base plate 470 in an expandable retractable manner. A lower portion of the outer bellows 460 is connected to the base plate 470. A portion where the outer bellows 460 and the base plate 470 are connected functions as a second flange. The outer bellows 460 is expanded and retracted as the support 410 is raised and lowered. The outer bellows 460 is expanded when raising the support 410, and is retracted when lowering the support 410. In other words, the direction of expansion and retraction of the outer bellows 460 when raising and lowering the support 410 is opposite to that of the inner bellows 450. The central axis of the outer bellows 460 may coincide with the central axis of the inner bellows 450. The inner diameter of the outer bellows 460 may be larger than the outer diameter of the inner bellows 450. The inner bellows 450 and the outer bellows 460 airtightly separate the internal space and the external space of the load lock chamber 120. By providing the inner bellows 450 and the outer bellows 460, it is possible to raise and lower the support 410 while maintaining the airtightness inside the load lock chamber 120. The outer bellows 460 is an example of a second expandable portion.

The lifting mechanism 400 is configured so that the torque for raising and lowering the first nut 422 relative to the first screw shaft 421 is different from the torque for raising and lowering the second nut 432 relative to the second screw shaft 431. Hereinafter, the torque for raising and lowering the first nut 422 relative to the first screw shaft 421 is referred to as a first torque, and the torque for raising and lowering the second nut 432 relative to the second screw shaft 431 is referred to as a second torque.

For example, the first torque and the second torque may be set to be different from each other by making the lead of the first screw shaft 421 and the lead of the second screw shaft 431 different. For example, the first torque and the second torque may be set to be different from each other by making the outer diameter of the first timing pulley 444 and the outer diameter of the second timing pulley 445 different. For example, the first torque and the second torque may be set to be different from each other by making the number of teeth of the first timing pulley 444 and the number of teeth of the second timing pulley 445 different.

The lifting mechanism 400 is configured, for example, so that the second torque is greater than the first torque. For example, the second torque may be set to be greater than the first torque by making the lead of the second screw shaft 431 greater than the lead of the first screw shaft 421. For example, the second torque may be set to be greater than the first torque by making the outer diameter of the second timing pulley 445 greater than the outer diameter of the first timing pulley 444. For example, the second torque may be set to be greater than the first torque by making the number of teeth of the second timing pulley 445 greater than the number of teeth of the first timing pulley 444.

The lifting mechanism 400 is configured, for example, so that the second torque is smaller than the first torque. For example, the second torque may be made smaller than the first torque by making the lead of the second screw shaft 431 smaller than the lead of the first screw shaft 421. For example, the second torque may be made smaller than the first torque by making the outer diameter of the second timing pulley 445 smaller than the outer diameter of the first timing pulley 444. For example, the second torque may be made smaller than the first torque by making the number of teeth of the second timing pulley 445 smaller than the number of teeth of the first timing pulley 444.

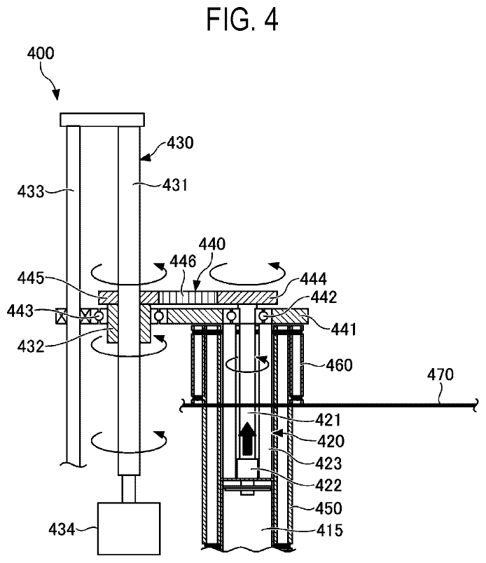

An example of the operation of the lifting mechanism 400 according to the first example will be described with reference to FIGS. 4 to 8. FIGS. 4 to 8 are cross-sectional views showing an example of the operation of the lifting mechanism 400 according to the first example. Hereinafter, an operation will be described in which, when the second torque is greater than the first torque, the support 410 is first raised from the lower end position to the upper end position, and then the support 410 is lowered from the upper end position to the lower end position.

FIG. 4 shows a state in which the support 410 is at the lower end position. As shown in FIG. 4, when the support 410 is at the lower end position, a length of the inner bellows 450 is longer than a length of the outer bellows 460.

As shown in FIG. 4, the second motor 434 rotates the second screw shaft 431 in the first direction. At this time, the second nut 432 is rotated in the first direction together with the second screw shaft 431 because the rotation direction of the second nut 432 is not restricted. That is, when the second screw shaft 431 rotates, the second nut 432 is rotated together with the second screw shaft 431. The second timing pulley 445 is fixed to the second nut 432. Therefore, when the second nut 432 rotates in the first direction, the second timing pulley 445 is rotated in the first direction together with the second nut 432. The timing belt 446 transmits the rotational force of the second timing pulley 445 to the first timing pulley 444. Therefore, when the second timing pulley 445 rotates in the first direction, the rotational force of the second timing pulley 445 is transmitted to the first timing pulley 444, and the first timing pulley 444 is rotated in the first direction. The first timing pulley 444 is fixed to the first screw shaft 421. Therefore, when the first timing pulley 444 rotates in the first direction, the first screw shaft 421 is rotated together with the first timing pulley 444 in the first direction. When the first screw shaft 421 rotates in the first direction, the first nut 422 starts to be raised along the first screw shaft 421. The shaft 415 is fixed to the first nut 422. Therefore, when the first nut 422 starts to be raised along the first screw shaft 421, the support 410 including the shaft 415 starts to be raised.

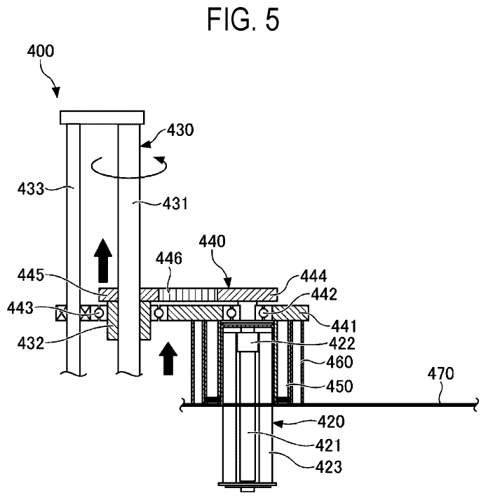

FIG. 5 shows a state in which the support 410 is at a first intermediate position during the rising movement from the lower end position to the upper end position. The illustration of the shaft 415 is omitted in FIG. 5. As shown in FIG. 5, when the support 410 is at the first intermediate position, the length of the inner bellows 450 is equal to the length of the outer bellows 460.

As shown in FIG. 5, when the first nut 422 is raised to the upper end of the first screw shaft 421, the first screw shaft 421 cannot rotate any further. Therefore, the rotation direction of the second nut 432 is restricted, and the second nut 432 is raised along the second screw shaft 431. As a result, the bracket 441, the first lifter 420, and the support 410 are raised.

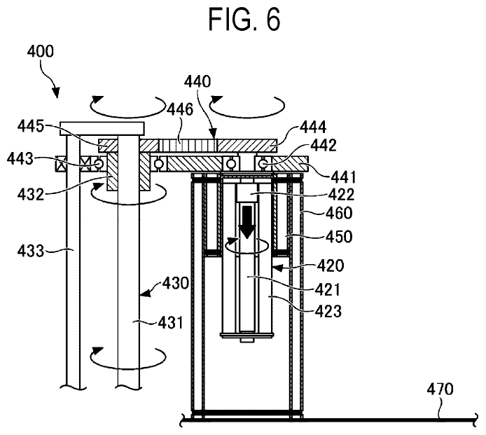

FIG. 6 shows a state in which the support 410 is at the upper end position. The illustration of the shaft 415 is omitted in FIG. 6. As shown in FIG. 6, when the support 410 is at the upper end position, the length of the inner bellows 450 is shorter than the length of the outer bellows 460.

As shown in FIG. 6, when the second nut 432 rises to the upper end of the second screw shaft 431, the bracket 441, the first lifter 420 and the support 410 are raised so that the support 410 reaches the upper end position.

As shown in FIG. 6, the second motor 434 rotates the second screw shaft 431 in the second direction. The second direction is the opposite direction to the first direction. At this time, the second nut 432 is rotated in the second direction together with the second screw shaft 431 because the rotation direction of the second nut 432 is not restricted. That is, when the second screw shaft 431 rotates, the second nut 432 is rotated together with the second screw shaft 431. The second timing pulley 445 is fixed to the second nut 432. Therefore, when the second nut 432 rotates in the second direction, the second timing pulley 445 is rotated in the second direction together with the second nut 432. The timing belt 446 transmits the rotational force of the second timing pulley 445 to the first timing pulley 444. Therefore, when the second timing pulley 445 rotates in the second direction, the rotational force of the second timing pulley 445 is transmitted to the first timing pulley 444, and the first timing pulley 444 is rotated in the second direction. The first timing pulley 444 is fixed to the first screw shaft 421. Therefore, when the first timing pulley 444 rotates in the second direction, the first screw shaft 421 is rotated together with the first timing pulley 444 in the second direction. When the first screw shaft 421 rotates in the second direction, the first nut 422 starts to be lowered along the first screw shaft 421. The shaft 415 is fixed to the first nut 422. Therefore, when the first nut 422 starts to be lowered along the first screw shaft 421, the support 410 including the shaft 415 starts to be lowered.

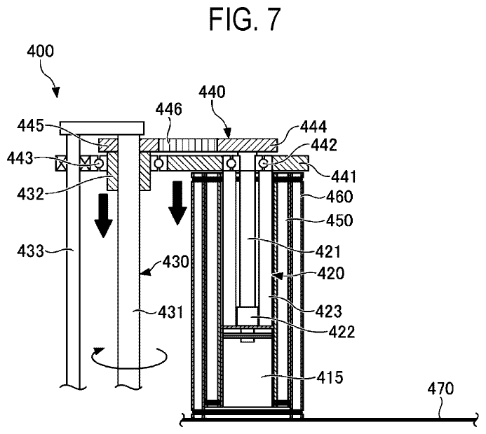

FIG. 7 shows a state in which the support 410 is at a second intermediate position during the lowering movement from the upper end position to the lower end position. As shown in FIG. 7, when the support 410 is at the second intermediate position, the length of the inner bellows 450 is equal to the length of the outer bellows 460. The lengths of the inner bellows 450 and the outer bellows 460 when the support 410 is at the second intermediate position are longer than the lengths of the inner bellows 450 and the outer bellows 460 when the support 410 is at the first intermediate position.

As shown in FIG. 7, when the first nut 422 is lowered to the lower end of the first screw shaft 421, the first screw shaft 421 cannot rotate any further. Therefore, the rotation direction of the second nut 432 is restricted, and the second nut 432 starts to be lowered along the second screw shaft 431. As a result, the bracket 441, the first lifter 420, and the support 410 start to be lowered.

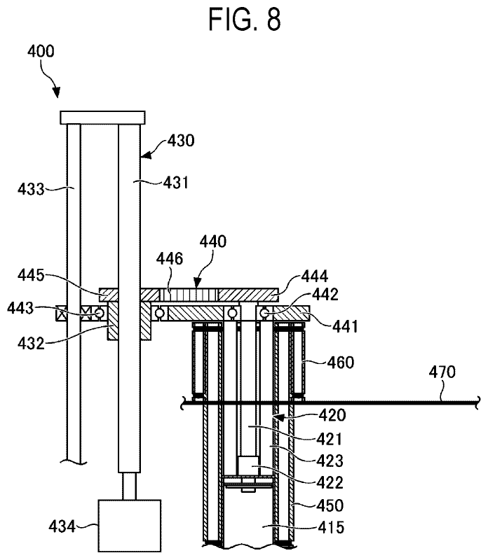

FIG. 8 shows a state in which the support 410 is at the lower end position. As shown in FIG. 8, when the support 410 is at the lower end position, the length of the inner bellows 450 is longer than the length of the outer bellows 460.

As shown in FIG. 8, when the second nut 432 is lowered to the lower end of the second screw shaft 431, the bracket 441, the first lifter 420 and the support 410 are lowered so that the support 410 reaches the lower end position.

As described above, according to one example of the operation of the lifting mechanism 400 of the first example, it is possible to raise and lower the support 410 between the upper end position and the lower end position by the driving force applied by the second motor 434. In this case, only one motor is required, which can reduce costs.

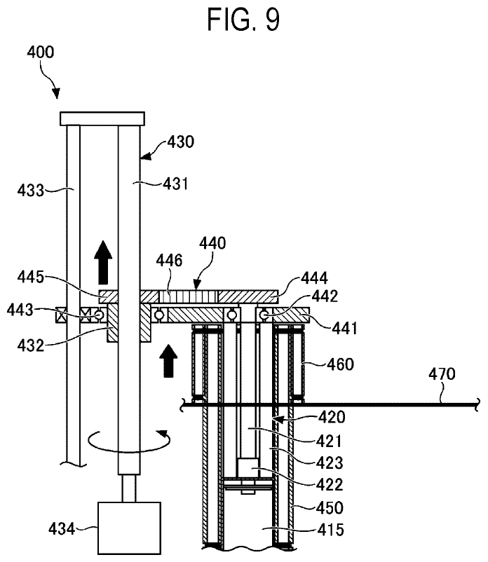

Another example of the operation of the lifting mechanism 400 according to the first example will be described with reference to FIGS. 9 to 13. FIGS. 9 to 13 are cross-sectional views showing another example of the operation of the lifting mechanism 400 according to the first example. Hereinafter, an operation will be described in which, when the second torque is smaller than the first torque, the support 410 is first raised from the lower end position to the upper end position, and then the support 410 is lowered from the upper end position to the lower end position.

FIG. 9 shows a state in which the support 410 is at the lower end position. As shown in FIG. 9, when the support 410 is at the lower end position, the length of the inner bellows 450 is longer than the length of the outer bellows 460.

As shown in FIG. 9, the second motor 434 rotates the second screw shaft 431 in the first direction. At this time, the rotation direction of the second nut 432 is not restricted, but the second torque is smaller than the first torque. Therefore, the second nut 432 does not rotate together with the second screw shaft 431, and is raised along the second screw shaft 431. That is, when the second screw shaft 431 rotates, the second nut 432 is raised along the second screw shaft 431 without co-rotation. As a result, the bracket 441, the first lifter 420, and the support 410 are raised.

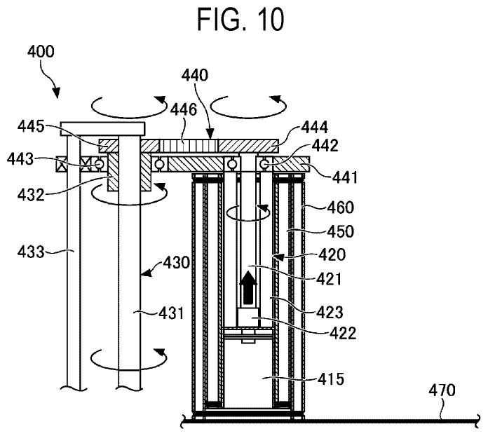

FIG. 10 shows a state in which the support 410 is at a third intermediate position during the rising movement from the lower end position to the upper end position. As shown in FIG. 10, when the support 410 is at the third intermediate position, the length of the inner bellows 450 is equal to the length of the outer bellows 460.

As shown in FIG. 10, when the second nut 432 reaches the upper end of the second screw shaft 431, the second nut 432 cannot be raised any further and therefore rotates together with the second screw shaft 431 in the first direction. That is, when the second screw shaft 431 rotates, the second nut 432 is rotated together with the second screw shaft 431. The second timing pulley 445 is fixed to the second nut 432. Therefore, when the second nut 432 rotates in the first direction, the second timing pulley 445 is rotated together with the second nut 432 in the first direction. The timing belt 446 transmits the rotational force of the second timing pulley 445 to the first timing pulley 444. Therefore, when the second timing pulley 445 rotates in the first direction, the rotational force of the second timing pulley 445 is transmitted to the first timing pulley 444, and the first timing pulley 444 is rotated in the first direction. The first timing pulley 444 is fixed to the first screw shaft 421. Therefore, when the first timing pulley 444 rotates in the first direction, the first screw shaft 421 is rotated in the first direction together with the first timing pulley 444. When the first screw shaft 421 rotates in the first direction, the first nut 422 starts to be raised along the first screw shaft 421. The shaft 415 is fixed to the first nut 422. Therefore, when the first nut 422 starts to be raised along the first screw shaft 421, the support 410 including the shaft 415 starts be raised.

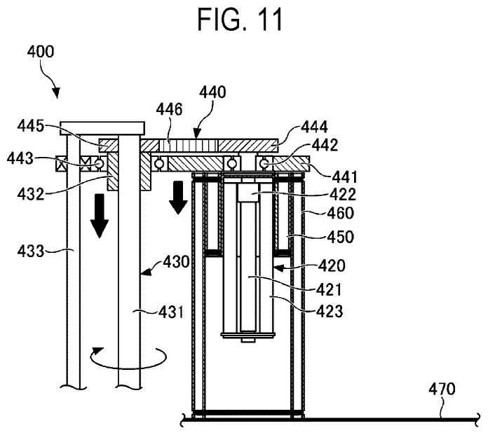

FIG. 11 shows a state in which the support 410 is at the upper end position. The shaft 415 is not shown in FIG. 11. As shown in FIG. 11, when the support 410 is at the upper end position, the length of the inner bellows 450 is shorter than the length of the outer bellows 460.

As shown in FIG. 11, when the first nut 422 is raised to the upper end of the first screw shaft 421, the support 410 including the shaft 415 reaches the upper end position.

As shown in FIG. 11, the second motor 434 rotates the second screw shaft 431 in a second direction. The second direction is the opposite direction to the first direction. At this time, the rotation direction of the second nut 432 is not restricted, but the second torque is smaller than the first torque. Therefore, the second nut 432 does not rotate together with the second screw shaft 431, and is lowered along the second screw shaft 431. That is, when the second screw shaft 431 rotates, the second nut 432 is lowered along the second screw shaft 431 without co-rotation. As a result, the bracket 441, the first lifter 420, and the support 410 are lowered.

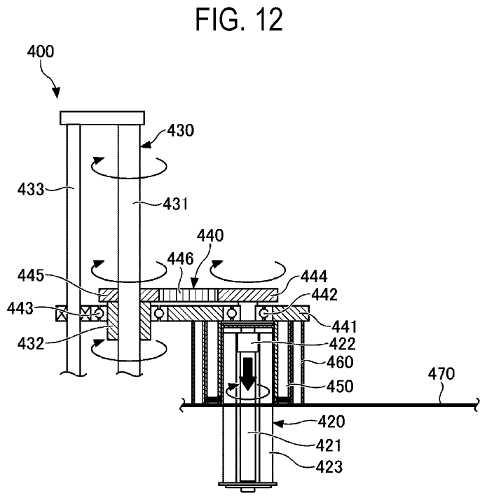

FIG. 12 shows a state in which the support 410 is at a fourth intermediate position during the lowering movement from the upper end position to the lower end position. As shown in FIG. 12, when the support 410 is at the fourth intermediate position, the length of the inner bellows 450 is equal to the length of the outer bellows 460. The lengths of the inner bellows 450 and the outer bellows 460 when the support 410 is at the fourth intermediate position are shorter than the lengths of the inner bellows 450 and the outer bellows 460 when the support 410 is at the third intermediate position.

As shown in FIG. 12, when the second nut 432 reaches the lower end of the second screw shaft 431, the second nut 432 cannot be lowered any further and therefore rotates together with the second screw shaft 431 in the second direction. That is, when the second screw shaft 431 rotates, the second nut 432 is rotated together with the second screw shaft 431. The second timing pulley 445 is fixed to the second nut 432. Therefore, when the second nut 432 rotates in the second direction, the second timing pulley 445 is rotated together with the second nut 432 in the second direction. The timing belt 446 transmits the rotational force of the second timing pulley 445 to the first timing pulley 444. Therefore, when the second timing pulley 445 rotates in the second direction, the rotational force of the second timing pulley 445 is transmitted to the first timing pulley 444, and the first timing pulley 444 is rotated in the second direction. The first timing pulley 444 is fixed to the first screw shaft 421. Therefore, when the first timing pulley 444 rotates in the second direction, the first screw shaft 421 is rotated in the second direction together with the first timing pulley 444. When the first screw shaft 421 rotates in the second direction, the first nut 422 starts to be lowered along the first screw shaft 421. The shaft 415 is fixed to the first nut 422. Therefore, when the first nut 422 starts to be lowered along the first screw shaft 421, the support 410 including the shaft 415 starts to be lowered.

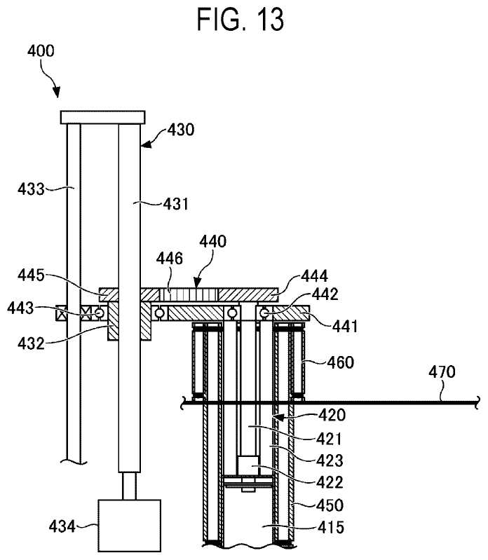

FIG. 13 shows a state in which the support 410 is at the lower end position. As shown in FIG. 13, when the support 410 is at the lower end position, the length of the inner bellows 450 is longer than the length of the outer bellows 460.

As shown in FIG. 13, when the first nut 422 is lowered to the lower end of the first screw shaft 421, the support 410 reaches the lower end position.

As described above, according to another example of the operation of the lifting mechanism 400 of the first example, the support 410 can be raised and lowered between the upper end position and the lower end position by the driving force applied by the second motor 434.

### Second Example

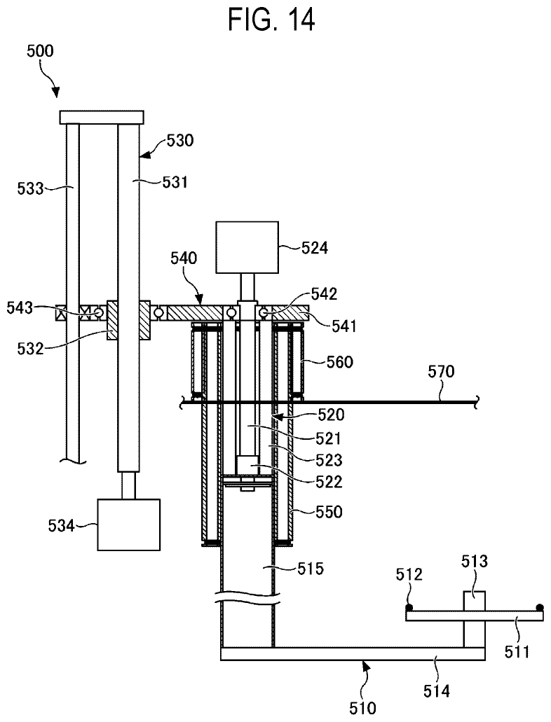

A lifting mechanism 500 according to a second example will be described with reference to FIG. 14. FIG. 14 is a cross-sectional view showing the lifting mechanism 500 according to the second example. The lifting mechanism 500 is applicable as the lifting mechanism 300 provided in the substrate processing apparatus 100. The lifting mechanism 500 differs from the lifting mechanism 400 in that the lifting mechanism 500 includes a first lifter 520 and a second lifter 530 that are driven independently of each other.

The lifting mechanism 500 includes a support 510, the first lifter 520, the second lifter 530, a connection portion 540, an inner bellows 550, and an outer bellows 560.

The support 510 supports the substrate holder WB. The support 510 includes a lid 511, a seal member 512, a rotary shaft 513, a support arm 514, and a shaft 515. The lid 511, the seal member 512, the rotary shaft 513, the support arm 514 and the shaft 515 may have the same configurations as the lid 411, the seal member 412, the rotary shaft 413, the support arm 414 and the shaft 415, respectively.

The first lifter 520 raises and lowers the support 510. The first lifter 520 includes a first screw shaft 521, a first nut 522, a first guide rail 523 and a first motor 524. The first screw shaft 521, the first nut 522 and the first guide rail 523 may have the same configurations as the first screw shaft 421, the first nut 422 and the first guide rail 423, respectively.

The first motor 524 applies a driving force to the first screw shaft 521 to rotate the first screw shaft 521. The first motor 524 may be connected to the upper end of the first screw shaft 521.

The second lifter 530 raises and lowers the first lifter 520. The second lifter 530 includes a second screw shaft 531, a second nut 532, a second guide rail 533 and a second motor 534. The second screw shaft 531, the second nut 532, the second guide rail 533 and the second motor 534 may have the same configurations as the second screw shaft 431, the second nut 432, the second guide rail 433 and the second motor 434, respectively.

The connection portion 540 includes a bracket 541, a first bearing 542, and a second bearing 543. The bracket 541, the first bearing 542 and the second bearing 543 may have the same configurations as the bracket 441, the first bearing 442 and the second bearing 443, respectively.

The inner bellows 550 and the outer bellows 560 may have the same configurations as the inner bellows 450 and outer bellows 460, respectively. The outer bellows 560 connects the inner bellows 550 and the base plate 570 in an expandable retractable manner.

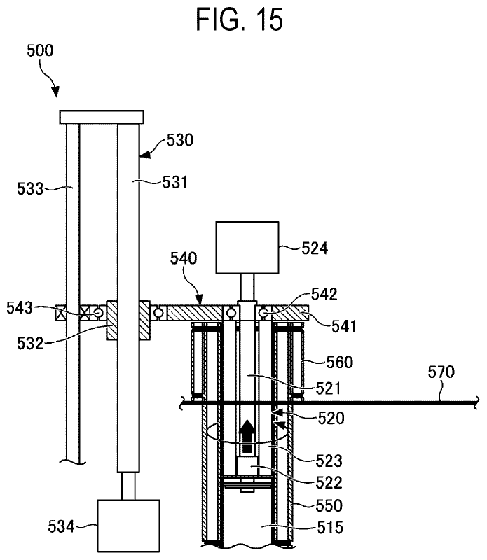

An example of the operation of the lifting mechanism 500 according to the second example will be described with reference to FIGS. 15 to 19. FIGS. 15 to 19 are cross-sectional views showing an example of the operation of the lifting mechanism 500 according to the second example. Hereinafter, the operation of first raising the support 510 from the lower end position to the upper end position and then lowering the support 510 from the upper end position to the lower end position will be described.

FIG. 15 shows a state in which the support 510 is at the lower end position. As shown in FIG. 15, when the support 510 is at the lower end position, a length of the inner bellows 550 is longer than a length of the outer bellows 560.

As shown in FIG. 15, the first motor 524 rotates the first screw shaft 521 in the first direction. Thus, the first nut 522 starts to be raised along the first screw shaft 521. The shaft 515 is fixed to the first nut 522. Therefore, when the first nut 522 starts to be raised along the first screw shaft 521, the support 510 including the shaft 515 starts to be raised.

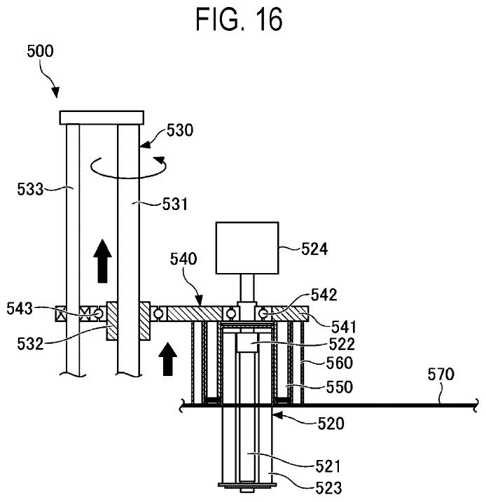

FIG. 16 shows a state in which the support 510 is at a first intermediate position during the rising movement from the lower end position to the upper end position. In FIG. 16, the shaft 515 is not illustrated. As shown in FIG. 16, when the support 510 is at the first intermediate position, the length of the inner bellows 550 is equal to the length of the outer bellows 560.

As shown in FIG. 16, when the first nut 522 rises to the upper end of the first screw shaft 521, the first motor 524 stops rotating the first screw shaft 521.

As shown in FIG. 16, the second motor 534 rotates the second screw shaft 531 in a first direction. Thus, the second nut 532 starts to be raised along the second screw shaft 531. As a result, the bracket 541, the first lifter 520 and the support 510 are raised. When the second nut 532 is raised to the upper end of the second screw shaft 531, the second motor 534 stops rotating the second screw shaft 531.

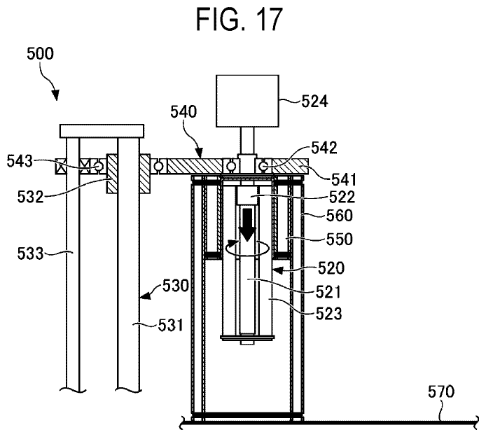

FIG. 17 shows a state in which the support 510 is at the upper end position. In FIG. 17, the illustration of the shaft 515 is omitted. As shown in FIG. 17, when the support 510 is at the upper end position, the length of the inner bellows 550 is shorter than the length of the outer bellows 560.

As shown in FIG. 17, when the second nut 532 is raised to the upper end of the second screw shaft 531, the support 510 reaches the upper end position.

As shown in FIG. 17, the first motor 524 rotates the first screw shaft 521 in a second direction. The second direction is the opposite direction to the first direction. Thus, the first nut 522 starts to descend along the first screw shaft 521. The shaft 515 is fixed to the first nut 522. Therefore, when the first nut 522 starts to be lowered along the first screw shaft 521, the support 510 including the shaft 515 starts to be lowered.

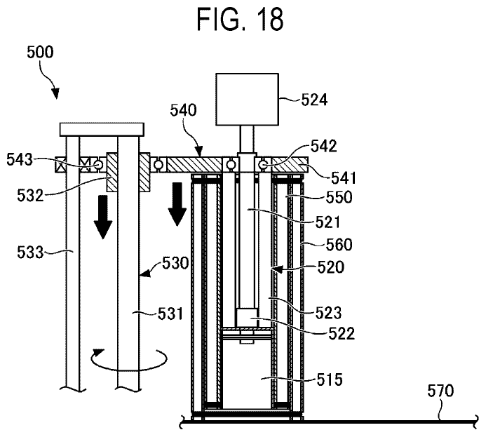

FIG. 18 shows a state in which the support 510 is at a second intermediate position during the lowering movement from the upper end position to the lower end position. As shown in FIG. 18, when the support 510 is at the second intermediate position, the length of the inner bellows 550 is equal to the length of the outer bellows 560. The lengths of the inner bellows 550 and the outer bellows 560 when the support 510 is at the second intermediate position are greater than the lengths of the inner bellows 550 and the outer bellows 560 when the support 510 is at the first intermediate position.

As shown in FIG. 18, when the first nut 522 is lowered to the lower end of the first screw shaft 521, the first motor 524 stops rotating the first screw shaft 521.

As shown in FIG. 18, when the first nut 522 is lowered to the lower end of the first screw shaft 521, the second motor 534 rotates the second screw shaft 531 in the second direction. Thus, the second nut 532 starts to be lowered along the second screw shaft 531. When the second nut 532 starts to be lowered along the second screw shaft 531, the bracket 541, the first lifter 520 and the support 510 start to descend. When the second nut 532 is lowered to the lower end of the second screw shaft 531, the second motor 534 stops rotating the second screw shaft 531.

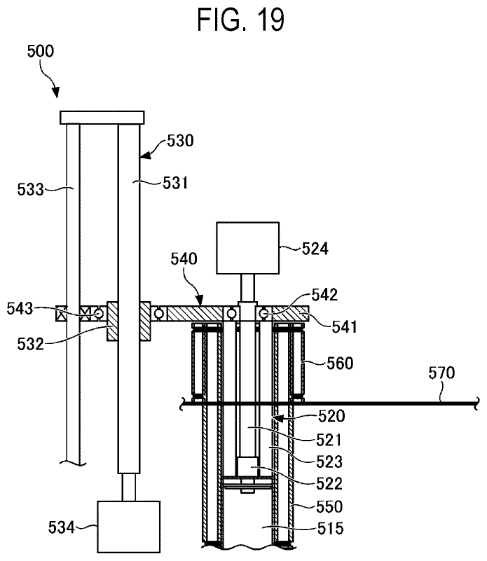

FIG. 19 shows a state in which the support 510 is at the lower end position. As shown in FIG. 19, when the support 510 is at the lower end position, the length of the inner bellows 550 is longer than the length of the outer bellows 560.

As shown in FIG. 19, when the second nut 532 descends to the lower end of the second screw shaft 531, the support 510 reaches the lower end position.

As described above, according to one example of the operation of the lifting mechanism 500 of the second example, it is possible to raise and lower the support 510 between the upper and lower end positions by the driving force applied by the first motor 524 and the second motor 534.

In the above-described embodiment, there has been described the case in which, when the support 510 is raised from the lower end position to the upper end position, the first motor 524 first rotates the first screw shaft 521 and then the second motor 534 rotates the second screw shaft 531. However, the present disclosure is not limited thereto. For example, when the support 510 is raised from the lower end position to the upper end position, the second motor 534 may first rotate the second screw shaft 531, and then the first motor 524 may rotate the first screw shaft 521. For example, when the support 510 is raised from the lower end position to the upper end position, the second motor 534 may rotate the second screw shaft 531 while the first motor 524 rotates the first screw shaft 521.

In the above-described embodiment, there has been described the case in which, when the support 510 is lowered from the upper end position to the lower end position, the first motor 524 first rotates the first screw shaft 521 and then the second motor 534 rotates the second screw shaft 531. However, the present disclosure is not limited thereto. For example, when the support 510 is lowered from the upper end position to the lower end position, the second motor 534 may first rotate the second screw shaft 531, and then the first motor 524 may rotate the first screw shaft 521. For example, when the support 510 is lowered from the upper end position to the lower end position, the second motor 534 may rotate the second screw shaft 531 while the first motor 524 rotates the first screw shaft 521.

### Second Embodiment

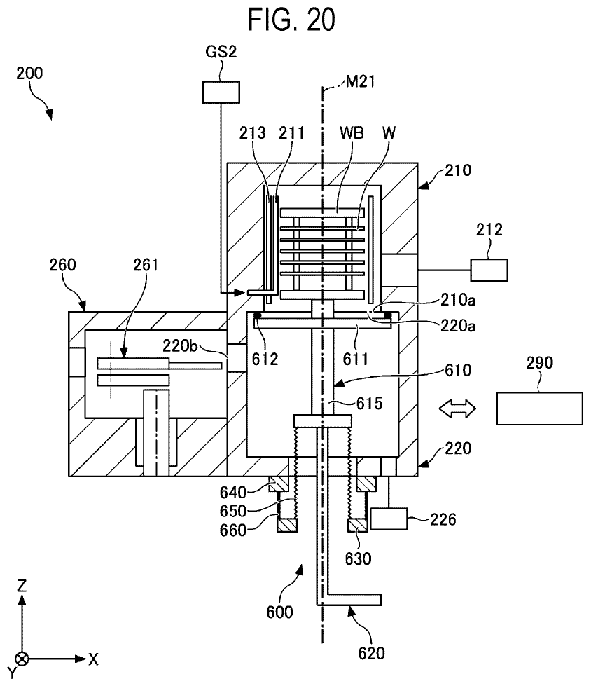

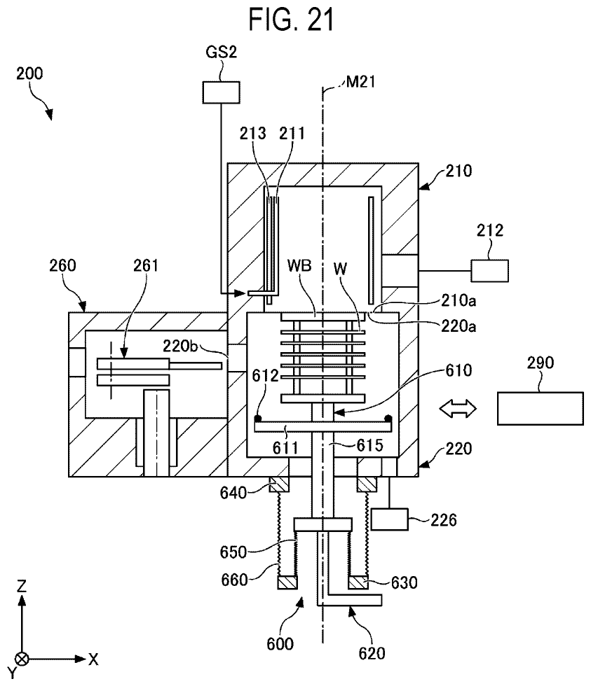

A substrate processing apparatus 200 according to a second embodiment will be described with reference to FIGS. 20 and 21. FIGS. 20 and 21 are cross-sectional views showing the substrate processing apparatus 200 according to the second embodiment. FIG. 20 shows a state in which the substrate holder WB is at the processing position. FIG. 21 shows a state in which the substrate holder WB is at the transfer position.

The substrate processing apparatus 200 includes a processing chamber 210, a load lock chamber 220, a substrate transfer chamber 260, and a controller 290.

The processing chamber 210 may have the same configuration as the processing chamber 110. A loading/unloading port 210a for loading and unloading the substrate holder WB is provided at the bottom of the processing chamber 210. A gas nozzle 211, an exhaust device 212 and a heater 213 are provided in the processing chamber 210. The gas nozzle 211, the exhaust device 212 and the heater 213 may have the same configurations as the gas nozzle 111, the exhaust device 112 and the heater 113. The gas nozzle 211 injects a processing gas supplied from the gas source GS2 from the periphery of the substrate holder WB located within the processing chamber 210 toward the substrate holder WB and the substrate W.

The load lock chamber 220 is located below the processing chamber 210. The load lock chamber 220 is capable of depressurizing an interior of the load lock chamber 220. The load lock chamber 220 accommodates the substrate holder WB therein. A loading/unloading port 220a for loading and unloading the substrate holder WB is provided at the top of the load lock chamber 220. The load lock chamber 220 communicates with the processing chamber 210 via the loading/unloading port 210a and the loading/unloading port 220a. The substrate holder WB is loaded from the load lock chamber 220 into the processing chamber 210 via the loading/unloading port 210a and the loading/unloading port 220a. The substrate holder WB is unloaded from the processing chamber 210 into the load lock chamber 220 via the loading/unloading port 210a and the loading/unloading port 220a. In the load lock chamber 220, the substrates W are loaded to and unloaded from the substrate holder WB. A loading/unloading port 220b for loading and unloading the substrates W is provided on a sidewall of the load lock chamber 220 on the negative side in the X-axis direction. The substrates W are loaded from the substrate transfer chamber 260 into the load lock chamber 220 via the loading/unloading port 220b. The substrates W are unloaded from the load lock chamber 220 into the substrate transfer chamber 260 via the loading/unloading port 220b. An exhaust device 226 and a lifting mechanism 600 are provided in the load lock chamber 220. The exhaust device 226 may have the same configuration as the exhaust device 126.

The lifting mechanism 600 is configured to raise and lower the substrate holder WB between the processing position (see FIG. 20) and the transfer position (see FIG. 21). The processing position may be a position where the entire substrate holder WB is accommodated in the processing chamber 210, and the loading/unloading port 210a and the loading/unloading port 220a are airtightly sealed by a lid 611. The transfer position may be a position located directly below the processing position, and may be a position where the entire substrate holder WB is accommodated within the load lock chamber 220. The transfer position may be a position where a part of the substrate holder WB faces the loading/unloading port 220b.

The lifting mechanism 600 includes a support 610, a lifter 620, a first flange 630, a second flange 640, an inner bellows 650, and an outer bellows 660.

The support 610 supports the substrate holder WB. The support 610 includes the lid 611, a seal member 612, and a shaft 615.

In a state in which the substrate holder WB is located in the processing chamber 210, the lid 611 airtightly seals the loading/unloading port 210a and the loading/unloading port 220a using the seal member 612. Thus, the interior of the processing chamber 210 is airtightly sealed. The seal member 612 is, for example, an O-ring. At the center of the lid 611, a through-hole is formed to penetrate the lid 611 in the vertical direction. A shaft 615 is inserted through the through-hole. The gap between the lid 611 and the shaft 615 is sealed by a magnetic fluid seal. The shaft 615 supports the substrate holder WB so as to be rotatable about the vertical axis M21. The shaft 615 penetrates through the bottom of load lock chamber 220 and extends to below the load lock chamber 220.

The lifter 620 is connected to the support 610. The lifter 620 raises and lowers the support 610 between the upper and lower end positions, thereby raising and lowering the substrate holder WB between the processing position and the transfer position. For example, the lifter 620 raises the support 610 from the lower end position to the upper end position, thereby loading the substrate holder WB from the transfer position to the processing position. For example, the lifter 620 lowers the support 610 from the upper end position to the lower end position, thereby unloading the substrate holder WB from the processing position to the transfer position.

The upper end position is a position where, as shown in FIG. 20, the length of the inner bellows 650 is longer than the length of the outer bellows 660. The upper end position may be a position where the length of the inner bellows 650 is at its maximum and the length of the outer bellows 660 is at its minimum. The upper end position may be a position where the lower surface of the shaft 615 is above the second flange 640. The upper end position may be a position where the lower surface of the shaft 615 is above the bottom of the load lock chamber 220.

The lower end position is a position where, as shown in FIG. 21, the length of the inner bellows 650 is shorter than the length of the outer bellows 660. The lower end position may be a position where the length of the inner bellows 650 is at its minimum and the length of the outer bellows 660 is at its maximum. The lower end position may be a position where the lower surface of the shaft 615 is at a height between the first flange 630 and the second flange 640. The lower end position may be a position where the lower surface of the shaft 615 is below the bottom of the load lock chamber 220.

The lifter 620 may be expandable. In this case, it is possible to reduce the amount of the lifter 620 protruding below the bottom of the load lock chamber 220. The lifter 620 expanded to raise the support 610. The lifter 620 is retracted to lower the support 610.

The first flange 630 is provided below the shaft 615. The first flange 630 has a circular ring plate shape. The height position of the first flange 630 is changeable.

The second flange 640 is provided above the first flange 630. The second flange 640 has a circular ring plate shape. The height position of the second flange 640 is fixed. The second flange 640 may be fixed to the bottom of the load lock chamber 220.

The inner bellows 650 has an expandable retractable bellows tube shape. The inner

bellows 650 connects the shaft 615 and the first flange 630 in an expandable retractable manner. The inner bellows 650 is expanded and retracted as the support 610 is raised and lowered. The inner bellows 650 is expanded when raising the support 610, and is retracted when lowering the support 610. The inner bellows 650 is an example of a first expandable portion.

The outer bellows 660 has an expandable retractable bellows tube shape. The outer bellows 660 is provided around the inner bellows 650. The outer bellows 660 connects the first flange 630 and the second flange 640 in an expandable retractable manner. The outer bellows 660 is expanded and retracted as the support 610 is raised and lowered. The outer bellows 660 is retracted when raising the support 610, and is expanded when lowering the support 610. In other words, the outer bellows 660 is expanded and retracted in a direction opposite to the expanding and retracting direction of the inner bellows 650 when raising and lowering the support 610. The central axis of the outer bellows 660 may coincide with the central axis of the inner bellows 650. The inner diameter of the outer bellows 660 may be larger than the outer diameter of the inner bellows 650. The inner bellows 650 and the outer bellows 660 airtightly separate the internal space and the external space of the load lock chamber 220. By providing the inner bellows 650 and the outer bellows 660, it is possible to raise and lower the support 610 while maintaining airtightness inside the load lock chamber 220. The outer bellows 660 is an example of a second expandable portion.

The substrate transfer chamber 260 may have the same configuration as the substrate transfer chamber 160. A substrate transfer robot 261 is provided in the substrate transfer chamber 260. The substrate transfer robot 261 may have the same configuration as the substrate transfer robot 161.

The controller 290 may have the same configuration as the controller 190.

As described above, according to the second embodiment, the lifting mechanism 600 includes the support 610, the lifter 620, the inner bellows 650, and the outer bellows 660. The support 610 supports the substrate holder WB. The lifter 620 is connected to the support 610 to raise and lower the support 610. The inner bellows 650 is expanded and retracted as the support 610 is raised and lowered. The outer bellows 660 is expanded and retracted as the support 610 is raised and lowered. The direction of expansion and contraction of the outer bellows 660 when lifting and lowering the support 610 is opposite to that of the inner bellows 650. In this case, when the support 610 is at the upper end position, a lower surface of the support 610 is located above the bottom of the load lock chamber 220. Therefore, the height at which the lower surface of the support 610 protrudes below the bottom of the load lock chamber 220 when the support 610 is lowered to the lower end position is reduced. As a result, it is possible to reduce the height of the substrate processing apparatus 200.

The embodiments disclosed herein should be considered to be exemplary and not limitative in all respects. The above-described embodiments may be omitted, substituted, or modified in various forms without departing from the scope and spirit of the appended claims.

According to the present disclosure in some embodiments, it is possible to reduce the height of an apparatus.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A lifting mechanism for raising and lowering a substrate holder that holds a plurality of substrates in a shelf-like manner, comprising:
a support configured to support the substrate holder;
a first lifter connected to the support and configured to raise and lower the support; and
a second lifter provided in parallel with the first lifter and configured to raise and lower the first lifter.

2. The lifting mechanism of claim 1, further comprising:
a transmission configured to transmit a driving force of the second lifter to the first lifter,
wherein the first lifter raises and lowers the support by the driving force transmitted from the second lifter via the transmission.

3. The lifting mechanism of claim 2, wherein the first lifter includes:
a first screw shaft extending vertically; and
a first nut fixed to the support and configured to be raised and lowered along the first screw shaft,
wherein the second lifter comprising:
a second screw shaft extending vertically;
a second nut configured to be raised and lowered along the second screw shaft; and
a second motor configured to apply a driving force to the second screw shaft, and
wherein the transmission transmits the driving force applied to the second screw shaft by the second motor to the first screw shaft.

4. The lifting mechanism of claim 3, wherein the transmission comprising:
a first timing pulley fixed to the first screw shaft;
a second timing pulley fixed to the second nut; and
a timing belt meshing with the first timing pulley and the second timing pulley.

5. The lifting mechanism of claim 4, wherein a torque for raising and lowering the first nut relative to the first screw shaft and a torque for raising and lowering the second nut relative to the second screw shaft are different from each other.

6. The lifting mechanism of claim 5, wherein a lead of the second screw shaft is different from a lead of the first screw shaft.

7. The lifting mechanism of claim 6, further comprising:
a first expandable portion configured to be expanded and retracted as the support is raised and lowered; and
a second expandable portion configured to be expanded and retracted as the support is raised and lowered, the second expandable portion expanded and retracted in a direction opposite to an expanding and retracting direction of the first expandable portion when raising and lowering the support.

8. The lifting mechanism of claim 5, wherein an outer diameter of the second timing pulley is different from an outer diameter of the first timing pulley.

9. The lifting mechanism of claim 5, wherein the number of teeth of the second timing pulley is different from the number of teeth of the first timing pulley.

10. The lifting mechanism of claim 3, wherein the transmission comprising:
a first bearing configured to rotatably support the first screw shaft;
a second bearing configured to rotatably support the second nut; and
a bracket to which the first bearing and the second bearing are fixed.

11. The lifting mechanism of claim 1, wherein the second lifter is driven independently of the first lifter.

12. The lifting mechanism of claim 1, further comprising:
a first expandable portion configured to be expanded and retracted as the support is raised and lowered; and
a second expandable portion configured to be expanded and retracted as the support is raised and lowered, the second expandable portion expanded and retracted in a direction opposite to an expanding and retracting direction of the first expandable portion when raising and lowering the support.

13. A substrate processing apparatus, comprising:
a substrate holder configured to hold a plurality of substrates in a shelf-like manner; and
a lifting mechanism configured to raise and lower the substrate holder,
wherein the lifting mechanism comprising:
a support configured to support the substrate holder;
a first lifter connected to the support and configured to raise and lower the support; and
a second lifter provided in parallel with the first lifter and configured to raise and lower the first lifter.

14. A lifting method for causing a lifting mechanism to raise and lower a substrate holder that holds a plurality of substrates in a shelf-like manner, the lifting mechanism including a support configured to support the substrate holder, a first lifter connected to the support and configured to raise and lower the support, and a second lifter provided in parallel with the first lifter and configured to raise and lower the first lifter, the lifting method comprising:
causing the first lifter and the second lifter to raise and lower the support.
